(19) United States
(12) Patent Application Publication
(10) Pub. No.: US 2006/0169583 A1
(43) Pub. Date: Aug. 3, 2006

(54) Sputtering device

(76) Inventor: Nobuyuki Takahashi, Sagamihara (JP)

Correspondence Address: WENDEROTH, LIND & PONACK, L.L.P., 2033 K STREET N. W., SUITE 800, WASHINGTON, DC, 20006-1021, US

(21) Appl. No.: 11/220,521

(22) Filed: Sep. 8, 2005

(30) Foreign Application Priority Data
Feb. 1, 2005 (JP) 2005-025076

(51) Int. Cl. C23C 14/00

(52) U.S. Cl. 204/298.02

(57) ABSTRACT

The present invention is to provide a sputtering device which can achieve film thickness distribution and coverage distribution desired at present in a simple constitution. Accordingly, the present invention is a sputtering device comprising at least; a substrate holder holding a substrate and revolving; sputtering cathode units each of which is provided with target for forming thin film on the substrate; driving arms for moving the sputtering cathode units arcuately to the substrate; and nozzle portions each of which is provided on the sputtering cathode unit so as to surround the target and has an opening facing to the substrate, wherein extending portions are provided on the opening of each nozzle portion so as to extend from both sides of the opening in moving direction of the sputtering cathode unit to a center portion of the opening, and the extending portions restrict sputtering particles before and behind the moving direction of the sputtering cathode unit.

### BACKGROUND OF THE INVENTION

The present invention relates to a sputtering device which is constituted of at least a substrate and a target for forming a thin film on the substrate, wherein atoms or molecules sputtered from the target by running ionized gas into the target are stuck on the substrate to form the thin film on the substrate.

A sputtering device disclosed in JP 2004-156122 A which is invented by the present applicant is that a substrate holder is rotated and a sputtering cathode unit is moved arcuately along the substrate revolving by being held on the substrate in order to increase film thickness distribution and coverage distribution.

Because evenness with high film thickness distribution and high coverage distribution is desired recently, delicate control is needed in order to achieve it. Concretely, as outer peripheral portion of the revolving substrate (a high speed portion) is brought near to a portion with a small quantity of sputtering particles scattered from the target (a low film thickness distribution portion) firstly or gone away lastly, it is necessary to decrease the movement speed of the sputtering cathode unit or the rotation speed of the substrate in order to secure the film thickness in the outer peripheral portion of the substrate when the sputtering cathode unit is brought near to the substrate or gone away from the substrate, so that there is a disadvantage such as to increase working time thereof.

### SUMMARY OF THE INVENTION

The present invention is to provide a sputtering device which can solve disadvantage arising when the sputtering cathode unit is brought near to the substrate or gone away from the substrate in a simplified constitution and achieve desired film thickness distribution and desired coverage distribution in a short time.

Accordingly, the present invention is a sputtering device comprising at least; a substrate holder holding a substrate and revolving; sputtering cathode units each of which is provided with a target for forming thin film on the substrate; driving arms for moving the sputtering cathode units arcuately to the substrate; and nozzle portions each of which is provided on the sputtering cathode unit so as to surround the target and has an opening facing to the substrate, wherein extending portions are provided on the opening of each nozzle portion so as to extend from both sides of the opening in moving direction of the sputtering cathode unit to a center portion of the opening, and the extending portions restrict sputtering particles; before and, behind the moving direction of the sputtering cathode unit.

Furthermore, it is desired that the extending portions are arcuate.

Accordingly, according to the present invention, since the extending portions prevent sputtering particles incident at a slant to the substrate when the opening of the nozzle in the sputtering cathode unit moves to a position where the opening faces to the substrate or after leaving from the substrate, unevenness of film thickness distribution and coverage distribution arisen between a center portion and a peripheral portion of the substrate can be prevented, and the above mentioned problems are resolved. Moreover, since it is not necessary to adjust moving speed or rotation speed of the sputtering cathode unit or the substrate, so that increase of the working time can be restrained.

### BRIEF DESCRIPTION OF DRAWINGS

FIG. 1 is a schematic diagram of the sputtering device according to the present invention;

FIG. 2 is a explanatory diagram showing structure of the extending portions of the nozzle;

FIG. 3 is a plan diagram showing an appearance that the sputtering cathode unit moves to the substrate; and

FIG. 4 is a side elevation diagram showing an appearance that the sputtering cathode unit moves to the substrate.

### DETAILED DESCRIPTION OF THE PREFERRED WORKING MODE

Hereinafter, a working mode of the present invention is explained by referring drawings.

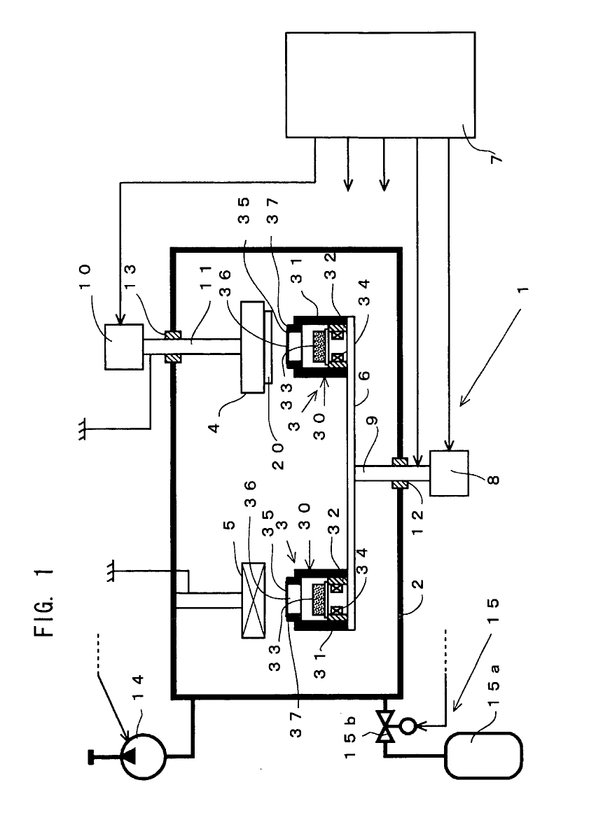

A sputtering device as shown in FIG. 1 has a vacuum chamber 2, and further has sputtering cathode units 3 each of which is provided with a sputtering cathode 30, a substrate holder 4 for holding a substrate 20 and a pre-sputtering mechanism 5 in the vacuum chamber 2.

The sputtering cathode units 3 are provided on end portions of a plurality of driving arms 6 extending to “radial directions from a rotation shaft 9 of an electric motor 8 controlled by a control unit 7, respectively. Thus, the arms 6 can rotate in both directions around the rotation shaft 9.

Besides, the substrate holder 4 is connected with a rotation shaft 11 of an electric motor 10 controlled by the control unit 7 to rotate by drive of the electric motor 10.

Furthermore, the rotation shaft 9 and the rotation shaft 11 are secured to the vacuum chamber 2 via seal mechanisms 12, 13, respectively.

The vacuum chamber 2 is provided with a vacuum pump 14 controlled by the control unit 7 and a gas supply mechanism 15 for supplying gas for sputtering (for instance, argon gas). Besides, in this working mode, the gas supply mechanism 15 is constituted of gas installation tank 15a and an electromagnetic valve 15b controlled by the control unit 7.

Furthermore, the sputtering cathode 30 is constituted of a grounded so shield portion 31 provided via an insulator 32, a nozzle portion 37 formed so as to project to a substrate side from the shield portion 31, a target 33 to which voltage is applied and which is arranged via the insulator 32 inside the shield portion 31 and magnets which are arranged behind the target 33. Besides, water for cooling and electric power are supplied via the rotation shaft 9 and the arms 6. Furthermore, a gap between a tip of the nozzle portion 30 of the sputtering cathode 30 and the substrate 20 is preferably as narrow as possible, but the best gap is set by considering in view of other parts, heat from the sputtering cathode 30 and so on.

The substrate holder 4 is grounded via the rotation shaft 11. Besides, in this working mode, since minus voltage is applied to the target 33, a ground side is an anode side, but there is a case that voltage is applied between the substrate holder 4 and the ground side.

In the sputtering device with the above constitution, pressure in the vacuum chamber 2 is decreased to 1×10⁻⁴ Pa (8×10⁻⁷ Torr) by controlling the vacuum pump 14. Then, the argon gas is introduced by controlling the electromagnetic valve 15b until the pressure in the vacuum chamber 2 becomes 1×10⁻¹Pa (5×10⁻³ Torr). Next, one of the sputtering cathode units 3 installing the desired target (for instance, Φ 50 mm Ta target) is moved to the pre-sputtering mechanism 5 by controlling the electric motor 8 to carry out a pre-sputtering operation by applying the electric power. In thus pre-sputtering operation, oxide and the like adhered on the target can be removed (cleaning). Besides, the pre-sputtering mechanism 5 is grounded, and it is set so as to be the same condition as discharge to the substrate. Furthermore, it is preferred that specific sensors are arranged in the pre-sputtering mechanism to test a sputtering condition and good sputtering is carried out on the substrate by adjusting the voltage, gas concentration and the like.

Then, the substrate 20 (for instance, Φ 200 mm Si substrate) held on the substrate holder 4 is rotated at a specific speed, for instance 10 rpm, by controlling the electric motor 10. Next, after a selected sputtering cathode unit 3 or sputtering cathode 30 is arranged at a position near the substrate holder 4, electric power (for instance, 1000WDC) is applied and the sputtering cathode unit 3 is moved along a surface of the substrate 20 for a thin film to be formed and in an arcuate track passing over the substrate 20 by controlling movement speed (0.1 rpm to 1 rpm) (a main sputtering). Fundamentally, the sputtering cathode unit 3 preferably moves, passes or reciprocates over the substrate 20 once or more.

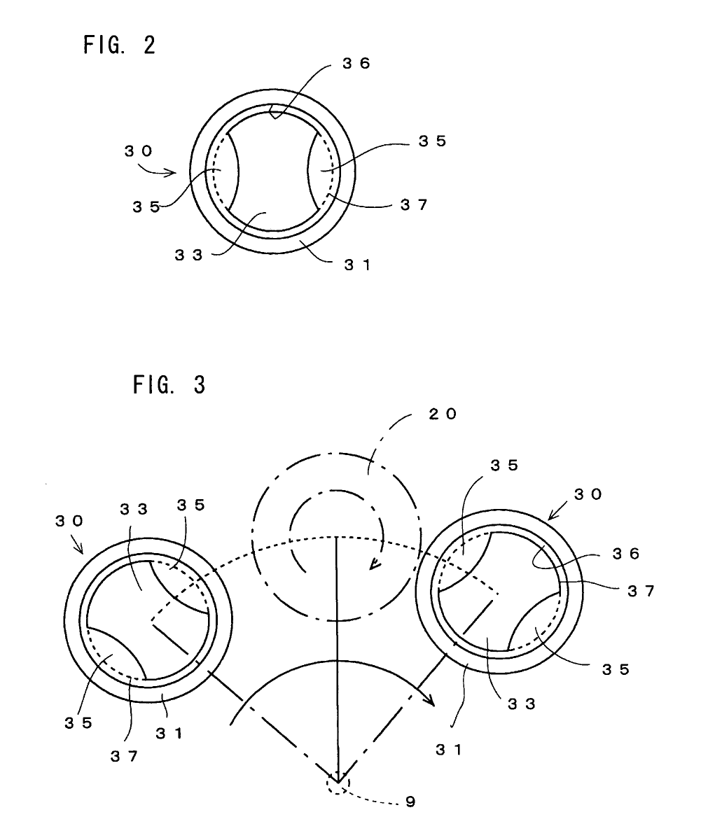

Next, the sputtering cathode unit 3 stops. If it is desired to continue a sputtering operation, the above mentioned operation is repeated, or if termination of the operation is desired, supply of the electric power is stopped, the agon gas is exhausted, and the pressure of the vacuum chamber is restored to normal air pressure to terminate the operation. in the sputtering cathode 30 in the sputtering device 1 with the above mentioned constitution, as shown in FIGS. 2 and 3, a pair of extending portions 35 is formed in an opening 36 which is opened in a substrate side of the nozzle portion 37. The extending portions 35 extend from two portions of a peripheral edge of the opening 36 which are before and behind in movement direction of the sputtering cathode unit 3 to a center of the opening 36 with specific widths, respectively.

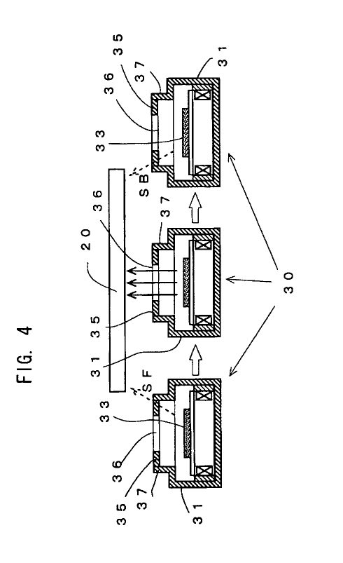

Thus, as shown in FIG. 4, when the sputtering cathode unit 3 approaches to the substrate 20, the extending portion 35 which is positioned before in the movement direction can prevent sputtering particles SF incident aslant to the substrate 20. Besides, when the sputtering cathode unit 3 leaves from the substrate 20, the extending portion 35 which is positioned behind in the movement direction can prevent sputtering particles SB incident aslant to the substrate 20, so that only approximately vertical sputtering particles are always poured to the substrate 20. Since approximately vertical sputtering particles are always poured to the substrate 20, forming film distribution and coverage distribution can be increased and desired forming film distribution and coverage distribution can be achieved.

What is claimed is:

1. A sputtering device comprising:
a substrate holder holding a substrate and rotating;
sputtering cathode units each of which is provided with a target for forming a thin film on the substrate;
driving arms which move said sputtering cathode units arcuately to the substrate, respectively; and
nozzles each of which is provided so as to surround said target and has an opening facing to the substrate;
wherein extending portions are provided in said opening so as to extend from both ends in movement direction of said sputtering cathode unit to a center of said opening, and
said extending portions restrict sputtering particles before and behind in the movement direction of the sputtering cathode unit.

2. A sputtering device according to claim 1, wherein
said extending portions are formed in an arcuate shape so as to project to a center side of said opening.
